(19) United States
(12) Patent Application Publication
(10) Pub. No.: US 2026/0280515 A1
(43) Pub. Date: Sep. 17, 2026

(54) ACOUSTIC WAVE DEVICE, FILTER, AND MULTIPLEXER

(71) Applicant: TAIYO YUDEN CO., LTD., Tokyo (JP)

(72) Inventor: Mayu TSUKADA, Tokyo (JP)

(73) Assignee: TAIYO YUDEN CO., LTD., Tokyo (JP)

(21) Appl. No.: 19/546,968

(22) Filed: Feb. 23, 2026

(30) Foreign Application Priority Data
Mar. 13, 2025 (JP) 2025-040489

(51) Int. Cl. H03H 9/02; H03H 9/145; H03H 9/25; H03H 9/64

(52) U.S. Cl. CPC H03H 9/02818; H03H 9/14541; H03H 9/25; H03H 9/6483

(57) ABSTRACT

An acoustic wave device includes a substrate, a piezoelectric layer provided on the substrate, and a pair of interdigitated electrodes provided on the piezoelectric layer, each of the interdigitated electrodes including a plurality of electrode fingers that excite an acoustic wave and a busbar to which the plurality of electrode fingers are connected. An anisotropic coefficient γ represented by kₓ²+γk_{y}²=k₀² is equal to or more than 1.7, where kₓ is a wavenumber of the acoustic wave in an arrangement direction of the plurality of fingers, k_{y} is a wavenumber of the acoustic wave in a longitudinal direction of the plurality of fingers, and k₀ is a wavenumber of the acoustic wave in a direction inclined from the arrangement direction toward the longitudinal direction.

### CROSS-REFERENCE TO RELATED APPLICATION

This application claims priority based on Japanese Patent Application No. 2025-040489 filed on Mar. 13, 2025, the entire contents of the Japanese patent applications are incorporated herein by reference.

### FIELD

A certain aspect of the present disclosure relates to an acoustic wave device, a filter, and a multiplexer.

### BACKGROUND

An acoustic wave device is used in a high-frequency communication system typified by a mobile phone. There has been known an acoustic wave device that includes a pair of interdigitated electrodes including a plurality of electrode fingers and a busbar to which the plurality of electrode fingers are connected, as an acoustic wave device (for example, Japanese Patent Application Publication No. 2020-129726 and Japanese Patent Application Publication No. 2017-112603). It is known that transverse mode spurious emissions can be reduced or prevented by setting the anisotropy coefficient in an intersection region in which a plurality of electrode fingers of a pair of interdigitated electrodes intersect with each other to be positive, setting the anisotropy coefficient in a gap region located between the electrode fingers and a busbar to be smaller than the anisotropy coefficient in the intersection region, and setting the acoustic velocity of the acoustic wave in the gap region to be equal to or lower than the acoustic velocity of the acoustic wave in the intersection region at the anti-resonant frequency (for example, Japanese Patent Application Publication No. 2017-112603).

### SUMMARY OF THE INVENTION

According to a first aspect of the present disclosure, there is provided an acoustic wave device including: a substrate; a piezoelectric layer provided on the substrate; and a pair of interdigitated electrodes provided on the piezoelectric layer, each of the interdigitated electrodes including a plurality of electrode fingers that excite an acoustic wave and a busbar to which the plurality of electrode fingers are connected; wherein an anisotropic coefficient γ represented by kₓ²+γk_{y}²=k₀² is equal to or more than 1.7, where kₓ is a wavenumber of the acoustic wave in an arrangement direction of the plurality of fingers, k_{y} is a wavenumber of the acoustic wave in a longitudinal direction of the plurality of fingers, and k₀ is a wavenumber of the acoustic wave in a direction inclined from the arrangement direction toward the longitudinal direction.

### BRIEF DESCRIPTION OF THE DRAWINGS

FIG. 1A is a plan view of an acoustic wave device according to a first embodiment.

FIG. 1B is a cross-sectional view taken along a line A-A in FIG. 1A.

FIG. 2A is a plan view of wavenumbers in an X direction and a Y direction in FIG. 1A.

FIG. 2B is a diagram illustrating kₓ/ω with respect to k_{y}/ω.

FIGS. 3A to 3E are diagrams illustrating simulation results of real part Real (Y) of admittance with respect to frequency.

FIGS. 4A to 4C are diagrams illustrating simulation results of anisotropy coefficient with respect to Young's modulus, density, or thickness of a tungsten layer.

FIG. 5A is a diagram illustrating a simulation result of anisotropy coefficient with respect to thickness of the tungsten layer.

FIGS. 5B and 5C are diagrams illustrating simulation results of anisotropy coefficient with respect to thicknesses of piezoelectric layer.

FIG. 6A is a plan view of an acoustic wave device according to a second embodiment.

FIG. 6B is a cross-sectional view taken along a line A-A in FIG. 6A.

FIG. 7A is a plan view of an IDT in the second embodiment.

FIG. 7B is a diagram illustrating the acoustic velocity of an acoustic wave in the second embodiment.

FIGS. 8A and 8B are cross-sectional views of electrode fingers in the second embodiment.

FIGS. 9A to 9D are diagrams illustrating simulation results of real part Real (Y) of admittance with respect to frequency.

FIG. 10A is a plan view of an acoustic wave device according to a first modification of the second embodiment.

FIG. 10B is a plan view of an acoustic wave device according to a second modification of the second embodiment.

FIG. 11A is a plan view of an acoustic wave device according to a third modification of the second embodiment.

FIG. 11B is a cross-sectional view taken along a line A-A in FIG. 11A.

FIG. 11C is a diagram illustrating an acoustic velocity of the acoustic wave in the third modification of the second embodiment.

FIG. 12A is a circuit diagram of a filter according to a third embodiment.

FIG. 12B is a circuit diagram of a duplexer according to a modification of the third embodiment.

### DESCRIPTION OF EMBODIMENTS

However, there is still room for improvement in terms of reducing the influence of transverse mode spurious emissions over a wide bandwidth.

The present disclosure has been made in view of the above problems, and an object of the present disclosure is to reduce the influence of transverse mode spurious emissions over a wide bandwidth.

Hereinafter, embodiments of the present disclosure will be described with reference to the drawings.

### First Embodiment

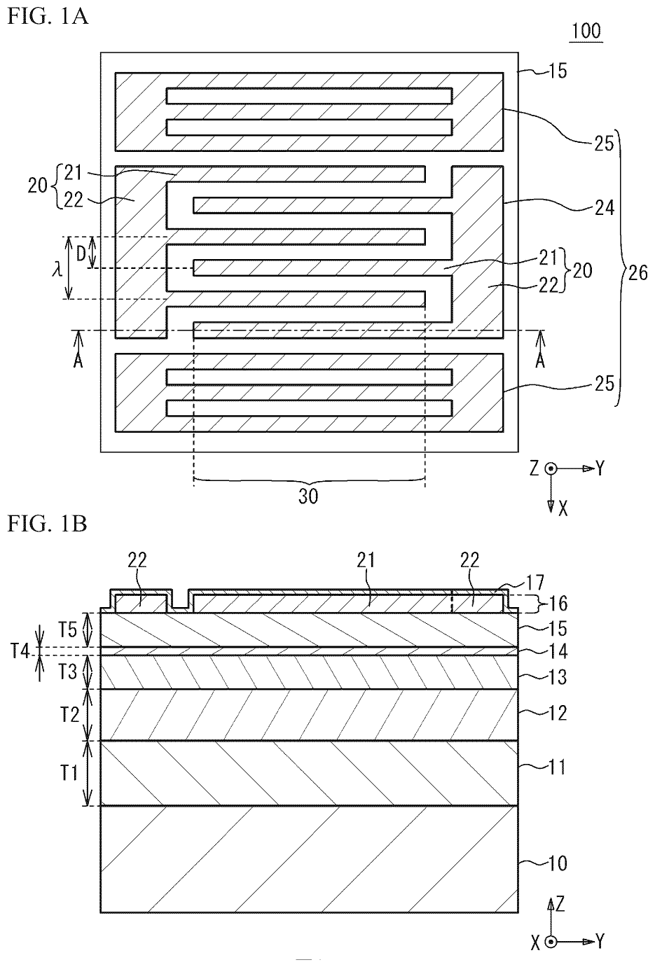

In a first embodiment, an example in which an acoustic wave device includes an acoustic wave resonator will be described. FIG. 1A is a plan view of an acoustic wave device 100 according to a first embodiment, and FIG. 1B is a cross-sectional view taken along a line A-A in FIG. 1A. An arrangement direction of a plurality of electrode fingers 21 is defined as an X direction, a longitudinal direction of the electrode fingers 21 is defined as a Y direction, and a stacking direction of a substrate 10 and a piezoelectric layer 15 is defined as a Z direction. The X direction, the Y direction, and the Z direction do not necessarily correspond to the X-axis direction and the Y-axis direction of the crystal orientation of the piezoelectric layer 15. When the piezoelectric layer 15 is a rotated Y-cut X-propagation piezoelectric layer, the X direction is the X-axis direction of the crystal orientation.

As illustrated in FIG. 1A and FIG. 1B, the piezoelectric layer 15 is provided on the substrate 10. A first insulating layer 11 is provided between the substrate 10 and the piezoelectric layer 15. A second insulating layer 12 is provided between the first insulating layer 11 and the piezoelectric layer 15. A third insulating layer 13 is provided between the second insulating layer 12 and the piezoelectric layer 15. A fourth insulating layer 14 is provided between the third insulating layer 13 and the piezoelectric layer 15. The thickness of the first insulating layer 11 is denoted by T1, the thickness of the second insulating layer 12 is denoted by T2, the thickness of the third insulating layer 13 is denoted by T3, the thickness of the fourth insulating layer 14 is denoted by T4, and the thickness of the piezoelectric layer 15 is denoted by T5.

The acoustic wave resonator 26 is provided on the piezoelectric layer 15. An acoustic wave resonator 26 includes an interdigital transducer (IDT) 24 and reflectors 25. The reflectors 25 are provided on both sides of the IDT 24 in the X direction. The IDT 24 and the reflector 25 are formed by a metal film 16 on the piezoelectric layer 15. An insulating film 17 is provided to cover the metal film 16.

The IDT 24 includes a pair of interdigitated electrodes 20 facing each other. The interdigitated electrode 20 includes the plurality of electrode fingers 21 and a busbar 22 to which the plurality of electrode fingers 21 are connected. A region where the electrode fingers 21 of the pair of interdigitated electrodes 20 intersect with each other is an intersection region 30. The length of the intersection region 30 in the Y direction is an aperture length. An anisotropy coefficient γ in the intersection region 30 is 1.7 or more. This point will be described later.

In the pair of interdigitated electrodes 20, the electrode fingers 21 are alternately provided one by one in at least a part of the intersection region 30. The acoustic wave excited mainly by the plurality of electrode fingers 21 in the intersection region 30 propagates mainly in the X direction. The pitch of the electrode fingers 21 of one of the pair of interdigitated electrodes 20 is substantially the wavelength λ of the acoustic wave. The wavelength λ is substantially twice an average pitch D of the plurality of electrode fingers 21. The average pitch D of the electrode fingers 21 can be calculated by dividing the length of the IDT 24 in the X direction by the number of the electrode fingers 21. The reflectors 25 reflect the acoustic wave (surface acoustic wave) excited by the electrode fingers 21 of the IDT 24. Thus, the acoustic wave is confined in the intersection region 30 of the IDT 24.

The piezoelectric layer 15 is, for example, a single crystal lithium tantalate (LiTaO₃) layer or a single crystal lithium niobate (LiNbO₃) layer, for example, a rotated Y-cut X-propagation lithium tantalate layer or a rotated Y-cut X-propagation lithium niobate layer. The thickness T5 of the piezoelectric layer 15 is preferably equal to or less than 1.0λ, and more preferably equal to or less than 0.7λ, from the viewpoint of suppressing spurious emissions and loss. The substrate 10 is, for example, a sapphire substrate, an alumina substrate, a silicon substrate, a spinel substrate, a quartz substrate, a quartz substrate, or a silicon carbide substrate. The linear expansion coefficient of the substrate 10 in the X direction is smaller than the linear expansion coefficient of the piezoelectric layer 15 in the X direction. This reduces the temperature dependence of the frequency of the acoustic wave resonator 26.

The acoustic velocity of the bulk wave propagating through the first insulating layer 11 and the second insulating layer 12 is higher than the acoustic velocity of the bulk wave propagating through the third insulating layer 13 and the piezoelectric layer 15. Accordingly, the energy of the acoustic wave of the main response is confined in the piezoelectric layer 15 and the third insulating layer 13. The first insulating layer 11 is, for example, polycrystalline or amorphous, and is an aluminum oxide layer, a silicon nitride layer, an aluminum nitride layer, a silicon carbide layer, or a polysilicon layer. In respect of confining the acoustic wave in the third insulating layer 13 and the piezoelectric layer 15, the thickness T1 of the first insulating layer 11 is preferably equal to or more than 0.3λ, and more preferably equal to or more than 1.0λ. In respect of improving the characteristics, the thickness T1 is preferably equal to or less than 10λ. The acoustic velocity of the bulk wave in each layer is the acoustic velocity Vs of the transverse wave, and is expressed by Equation 1, where G is a rigidity and p is a density.

$${V}_{S} = \sqrt{\frac{G}{ϱ}} \qquad [ Equation 1 ]$$

The rigidity G is expressed by Equation 2, where E is a Young's modulus and v is a Poisson's ratio.

$$G = \frac{E}{2 ( 1 + v )} \qquad [ Equation 2 ]$$

The Poisson's ratio vis 0.2 to 0.3, and is typically 0.25. Therefore, the acoustic velocity of the bulk wave in each layer can be calculated by measuring the Young's modulus and the density of each layer.

The third insulating layer 13 is, for example, a temperature compensation film, and has a temperature coefficient of an elastic constant having a sign opposite to a sign of a temperature coefficient of an elastic constant of the piezoelectric layer 15. For example, the temperature coefficient of the elastic constant of the piezoelectric layer 15 is negative, and the temperature coefficient of the elastic constant of the third insulating layer 13 is positive. The third insulating layer 13 is, for example, a silicon oxide (SiO₂) layer that is undoped or contains an additive element such as fluoride, phosphorus, or boron, and is, for example, polycrystalline or amorphous. This reduces the temperature coefficient of frequency of the acoustic wave resonator 26. When the third insulating layer 13 is a silicon oxide layer, the acoustic velocity of the bulk wave propagating through the third insulating layer 13 is lower than the acoustic velocity of the bulk wave propagating through the piezoelectric layer 15.

In order for the third insulating layer 13 to have a temperature compensation function, it is required that the energy of the acoustic wave of the main response is present to some extent in the third insulating layer 13. The range in which the energy of the surface acoustic wave is concentrated depends on the type of the surface acoustic wave, but the energy is typically concentrated in a range of 2.0λ from the upper surface of the piezoelectric layer 15, and particularly concentrated in a range of 1.0λ from the upper surface of the piezoelectric layer 15. Therefore, a length (T3+T4+T5) from the lower surface of the third insulating layer 13 to the upper surface of the piezoelectric layer 15 is preferably equal to or less than 2.0λ, and more preferably equal to or less than 1.0λ.

The second insulating layer 12 is a reflective layer that reflects the acoustic wave of the main response. The acoustic velocity of the bulk wave propagating through the second insulating layer 12 is higher than the acoustic velocity of the bulk wave propagating through the first insulating layer 11. The second insulating layer 12 is, for example, polycrystalline or amorphous, and is an aluminum nitride layer, a silicon nitride layer, a silicon carbide layer, or a diamond-like carbon (DLC) layer. The thickness T2 of the second insulating layer 12 is preferably equal to or less than 2.0λ, and more preferably equal to or less than 1.5λ.

The fourth insulating layer 14 is a bonding layer that bonds the third insulating layer 13 and the piezoelectric layer 15. The acoustic velocity of the acoustic wave propagating through the fourth insulating layer 14 is higher than the acoustic velocity of the acoustic wave propagating through the third insulating layer 13. The fourth insulating layer 14 is, for example, polycrystalline or amorphous, and is, for example, an aluminum oxide layer, a silicon layer, an aluminum nitride layer, an aluminum oxynitride layer, a diamond-like carbon layer, a silicon nitride layer, or a silicon carbide layer. The thickness of the fourth insulating layer 14 is preferably equal to or less than 20 nm, and more preferably equal to or less than 10 nm, from the viewpoint of not impairing the functions of the piezoelectric layer 15 and the third insulating layer 13. From the viewpoint of not impairing the function as the fourth insulating layer 14, the thickness of the fourth insulating layer 14 is preferably equal to or more than 1 nm, and more preferably equal to or more than 2 nm.

The metal film 16 is a film containing a material having a high density and a high Young's modulus as a main component, and is a film containing, for example, tungsten (W), molybdenum (Mo), iridium (Ir), or gold (Au) as a main component. The electrode finger 21 may include an adhesion film such as a titanium (Ti) film, a chromium (Cr) film, or a titanium nitride (TiN) film between the metal film 16 and the piezoelectric layer 15. The adhesion film is thinner than the metal film 16.

Here, in order to make a certain film contain a certain element as a main component, the certain film may contain an intentional or unintentional impurity other than the main component. When the certain element is the main component in the certain film, the concentration of the certain element is, for example, 50 atomic % or more, and for example, 80 atomic % or more. In the case where two elements are the main components as in silicon oxide or the like, the total of the concentration of silicon and the concentration of oxygen is, for example, 50 atomic % or more, for example, 80 atomic % or more, and each of the concentration of silicon and the concentration of oxygen is, for example, 10 atomic % or more.

### [Production Method]

A method of manufacturing the acoustic wave device 100 according to the first embodiment will be described. First, the first insulating layer 11, the second insulating layer 12, the third insulating layer 13, and the fourth insulating layer 14 are formed in this order on the substrate 10. The first insulating layer 11, the second insulating layer 12, the third insulating layer 13, and the fourth insulating layer 14 are formed by using, for example, a sputtering method, a chemical vapor deposition (CVD) method, or a vacuum deposition method. Next, the piezoelectric layer 15 is bonded to the fourth insulating layer 14 by using, for example, a surface activation method, and then the piezoelectric layer 15 is polished to have a desired thickness by using, for example, a chemical mechanical polishing (CMP) method. Next, after the metal film 16 is formed on the piezoelectric layer 15, the metal film 16 is patterned into a desired shape. This forms the IDT 24 and the reflectors 25 on the piezoelectric layer 15. The metal film 16 is formed by, for example, the sputtering method, the CVD method, or the vacuum deposition method. The patterning of the metal film 16 is performed by, for example, a photolithography method and an etching method. Thus, the acoustic wave device 100 according to the first embodiment is formed.

### [Anisotropy Coefficient]

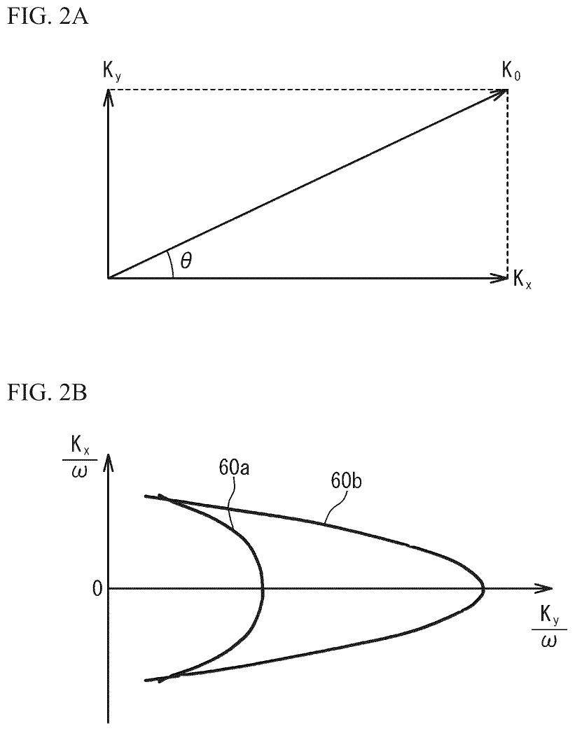

FIG. 2A is a plan view of wavenumbers in the X direction and the Y direction in FIG. 1A, and FIG. 2B is a diagram illustrating kₓ/ω with respect to k_{y}/ω. In FIG. 2B, kₓ/ω corresponds to the reverse velocity of the X direction component, and k_{y}/ω corresponds to the reverse velocity of the Y direction component. As illustrated in FIG. 2A, the wavenumber of the acoustic wave in the X direction is denoted by kₓ, and the wavenumber of the acoustic wave in the Y direction is denoted by k_{y}. When the wavenumber k₀ of the acoustic wave in the direction rotated from the X direction to the Y direction by the angle θ can be approximated by a parabola with respect to the angle θ, the wavenumber k₀ is expressed by k_{y}²+γ·k_{y}²=k₀² using the anisotropic coefficient γ.

As illustrated in FIG. 2B, when the anisotropic coefficient γ is positive, the reverse velocity planes 60a and 60b are convex when viewed from an origin. Therefore, the case where the anisotropy coefficient γ>0 is also referred to as a convex type. The reverse velocity plane when the anisotropy coefficient γ is small is indicated by 60a, and the reverse velocity plane when the anisotropy coefficient γ is large is indicated by 60b. The ratio of kₓ/ω to k_{y}/ω is smaller in the reverse velocity plane 60b when the anisotropic coefficient γ is large than in the reverse velocity plane 60a when the anisotropic coefficient γ is small. In general, in order to suppress the transverse mode spurious emissions, the anisotropic coefficient γ is reduced to form a shape close to an arc such as the reverse velocity plane 60a. However, it is difficult to reduce the anisotropic coefficient γ depending on the material of the electrode finger 21, and the shape of the surface may be an elliptic arc such as the reverse velocity plane 60b.

### [Simulation 1: Simulation on Transverse Mode Spurious Emissions]

A simulation was performed using two dimensional analysis software to examine the transverse mode spurious emissions when the anisotropy coefficient γ in the intersection region 30 was varied in the first embodiment. The simulation conditions are as follows.
Wavelength λ of acoustic wave: 4.17 μm
Number of pairs of electrode fingers 21: 100 pairs
Aperture length: 15λ
Duty ratio: 50%
Length of gap in Y direction: 1λ
Anisotropy coefficient γ of intersection region 30: 0.3, 1.7, 3.0, 10, 17

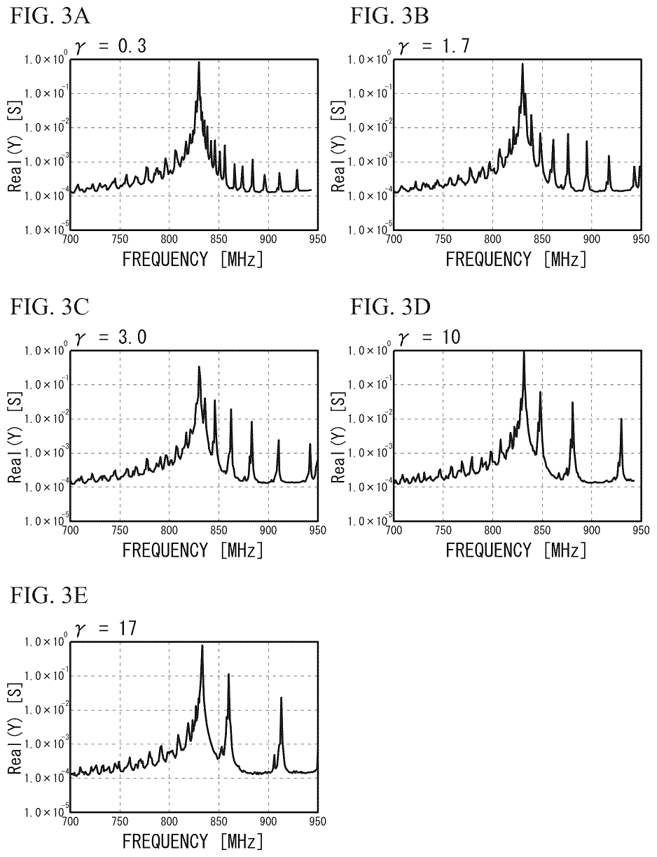

FIGS. 3A to 3E are diagrams illustrating simulation results of real part Real (Y) of admittance with respect to frequency. FIG. 3A illustrates the results when the anisotropy coefficient γ is 0.3, FIG. 3B illustrates the results when γ is 1.7, FIG. 3C illustrates the results when γ is 3.0, FIG. 3D illustrates the results when γ is 10, and FIG. 3E illustrates the results when γ is 17. As illustrated in FIG. 3A, when the anisotropy coefficient γ is 0.3, many transverse mode spurious emissions occur on the higher frequency side than the resonant frequency. As illustrated in FIGS. 3B to 3E, as the anisotropy coefficient γ increases, the interval of the transverse mode spurious emissions increases on the higher frequency side than the resonant frequency, and the number of transverse mode spurious emissions decreases in the range from the resonant frequency to the predetermined frequency. That is, the number of transverse mode spurious emissions is reduced in a wide frequency range on the higher frequency side than the resonant frequency. For example, the number of transverse mode spurious emissions in the band between the resonant frequency and 950 MHz is about 14 when the anisotropic coefficient γ is 0.3, whereas the number of transverse mode spurious emissions is reduced to about 9 when the anisotropic coefficient γ is 1.7. The number of transverse mode spurious emissions is reduced to about 6 when the anisotropy coefficient γ is 3.0, to about 3 when γ is 10, and to about 2 when γ is 17.

From the results of the simulation 1, it is understood that, by setting the anisotropy coefficient γ to 1.7 or more, the interval of the transverse mode spurious emissions increases on the higher frequency side than the resonance frequency, and the influence of the transverse mode spurious emissions can be reduced in the wide frequency range on the higher frequency side than the resonance frequency. Therefore, in the first embodiment, as described above, the anisotropy coefficient γ in the intersection region 30 is set to 1.7 or more.

### [Simulation 2: Simulation on Anisotropy Coefficient γ]

A simulation was performed using two dimensional analysis software with respect to the anisotropy coefficient γ when the Young's modulus, the density, and the thickness of the electrode finger 21 were changed in the first embodiment. The simulation conditions are as follows.
Wavelength λ of acoustic wave: 4.17 μm
Substrate 10: sapphire substrate
First insulating layer 11: aluminum oxide (Al₂O₃) layer having thickness T1 of 9.0 μm
Second insulating layer 12: aluminum nitride (AlN) layer having thickness T2 of 2.0 μm
Third insulating layer 13: silicon oxide (SiO₂) layer having thickness T3 of 0.417 μm
Fourth insulating layer 14: none
Piezoelectric layer 15: 36° rotated Y-cut X-propagation lithium tantalate layer having thickness T5 of 0.417 μm
Electrode finger 21: multilayer film of titanium (Ti) layer having thickness of 10 nm, tungsten (W) layer having thickness of 10 nm, and aluminum (Al) layer having thickness of 300 nm
Insulating film 17: silicon oxide (SiO₂) film having thickness of 15 nm
   With reference to the Young's modulus (411 GPa) and density (19.25 g/cm³) of general W, the Young's modulus of W layer of the electrode finger 21 is changed between 370 GPa and 452 GPa, and the density is changed between 17.40 g/cm³ and 21.30 g/cm³. The thickness of W layer of the electrode finger 21 is changed between 250 nm and 400 nm.

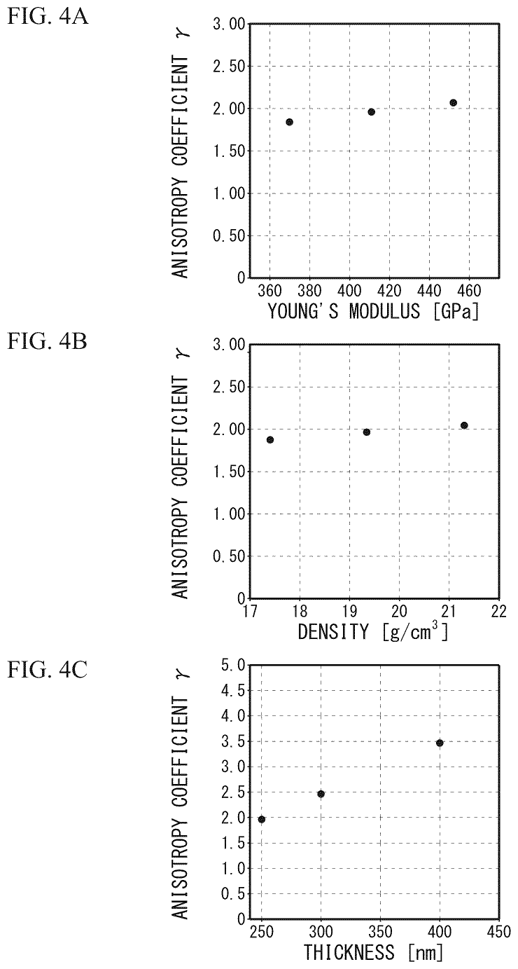

FIGS. 4A to 4C are diagrams illustrating simulation results of anisotropy coefficient γ with respect to Young's modulus, density, or thickness of the tungsten (W) layer. FIG. 4A is a diagram illustrating anisotropic coefficient γ with respect to Young's modulus of the W layer when the density of the W layer is fixed to 19.25 g/cm³ and the thickness thereof is fixed to 250 nm. FIG. 4B is a diagram illustrating anisotropic coefficients γ with respect to density of the W layer when the Young's modulus of the W layer is fixed to 411 GPa and the thickness thereof is fixed to 250 nm. FIG. 4C is a diagram illustrating anisotropic coefficient γ with respect to thickness of the W layer when the Young's modulus of the W layer is fixed to 411 GPa and the density thereof is fixed to 19.25 g/cm³.

As illustrated in FIGS. 4A to 4C, as the Young's modulus of the W layer increases, as the density thereof increases, or as the thickness thereof increases, the anisotropy coefficient γ increases, and becomes, for example, 1.7 or more. This shows that the anisotropy coefficient γ is 1.7 or more by using a film containing a material having a large Young's modulus and a large weight as a main component for the electrode finger 21 and increasing the thickness of the film.

Next, a simulation was performed using two dimensional analysis software for the range of the anisotropy coefficient γ. The simulation conditions are as follows.
Wavelength λ of acoustic wave: 1.0 μm to 5.0 μm
Substrate 10: sapphire substrate
First insulating layer 11: aluminum oxide (Al₂O₃) layer having thickness T1 of 6.17 μm
Second insulating layer 12: none
Third insulating layer 13: silicon oxide (SiO₂) layer having thickness T3 of 0.1λ to 0.3λ
Fourth insulating layer 14: none
Piezoelectric layer 15: 36° rotated Y-cut X-propagation lithium tantalate layer having thickness T5 of 0.05λ to 0.5λ
Electrode finger 21: multilayer film of titanium (Ti) layer having thickness of 10 nm, and tungsten (W) layer having thickness of 250 to 500 nm
Insulating film 17: none

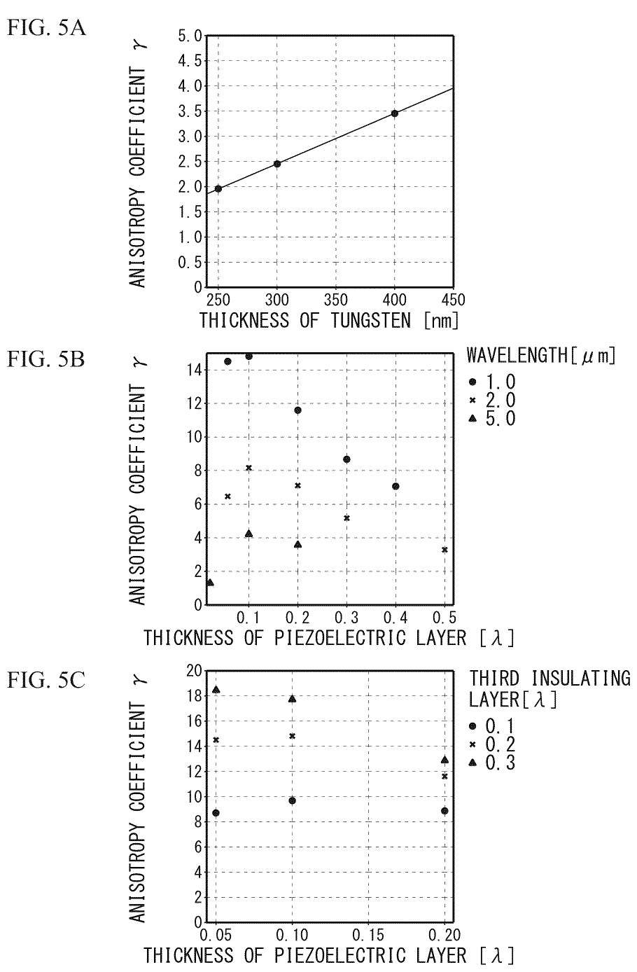

FIG. 5A is a diagram illustrating a simulation result of anisotropy coefficient γ with respect to thickness of the tungsten (W) layer. The result is obtained when the wave length λ of the acoustic wave is 4.17 μm, the thickness of the piezoelectric layer 15 is 0.1λ, and the thickness T3 of the third insulating layer 13 is 0.1λ. A straight line in FIG. 5A is an approximate straight line. As illustrated in FIG. 5A, the anisotropic coefficient γ increases as the thickness of the W layer increases, and the anisotropic coefficient γ is 1.7 or more when the thickness of the W layer is equal to more than 250 nm. When the thickness of the W layer is equal to or more than 300 nm, the anisotropic coefficient γ is equal to or more than about 2.5, when the thickness of the W layer is equal to or more than 350 nm, the anisotropic coefficient γ is equal to or more than about 3.0, when the thickness of the W layer is equal to or more than 400 nm, the anisotropic coefficient γ is equal to or more than about 3.5, and when the thickness of the W layer is equal to or more than 450 nm, the anisotropic coefficient γ is equal to or more than about 4.0.

FIGS. 5B and 5C are diagrams illustrating simulation results of anisotropic coefficient γ with respect to thickness T5 of the piezoelectric layer 15. FIG. 5B is a diagram illustrating anisotropy coefficient γ with respect to thickness T5 of the piezoelectric layer 15 when the thickness of the W layer is fixed to 500 nm and the thickness T3 of the third insulating layer 13 is fixed to 0.2λ. FIG. 5C is a diagram illustrating the anisotropy coefficient γ with respect to thickness T5 of the piezoelectric layer 15 when the thickness of the W layer is fixed to 500 nm and the wavelength λ of the acoustic wave is fixed to 1.0 μm.

As illustrated in FIG. 5B, even when the wavelengths 2 of the acoustic waves are different, the anisotropic coefficient γ is large when the thickness T5 of the piezoelectric layer 15 is 0.1λ. When the thickness of the W layer is 500 nm and the thickness T3 of the third insulating layer 13 is 0.2λ, the anisotropic coefficient γ is 5.0 or more when the wave length λ of the acoustic wave is 2.0 μm or less and the thickness T5 of the piezoelectric layer 15 is 0.3λ or less. When the wave length λ of the acoustic wave is equal to or less than 1.0 μm and the thickness T5 of the piezoelectric layer 15 is equal to or less than 0.2λ, the anisotropic coefficient γ is equal to or more than 11.

As illustrated in FIG. 5C, the anisotropic coefficient γ increases as the thickness T3 of the third insulating layer 13 increases. In a case where the thickness of the W layer is 500 nm and the wave length λ of the acoustic wave is 1.0 μm, the anisotropic coefficient γ is 8.0 or more when the thickness T3 of the third insulating layer 13 is 0.1λ or more and the thickness T5 of the piezoelectric layer 15 is 0.05λ or more and 0.20λ or less. The anisotropic coefficient γ is 11 or more when the thickness T3 of the third insulating layer 13 is 0.2λ or more and the thickness T5 of the piezoelectric layer 15 is 0.05λ or more and 0.20λ or less. The anisotropic coefficient γ is 14 or more when the thickness T3 of the third insulating layer 13 is 0.2λ or more and the thickness T5 of the piezoelectric layer 15 is 0.05λ or more and 0.10λ or less. The anisotropic coefficient γ is 17 or more when the thickness T3 of the third insulating layer 13 is 0.3λ or more and the thickness T5 of the piezoelectric layer 15 is 0.05λ or more and 0.10λ or less.

As described above, the anisotropic coefficient γ can be set to at least a range of 1.7 or more and 20 or less by adjusting the material and thickness of the piezoelectric layer 15, the thickness T5 of the piezoelectric layer 15, and the thickness T3 of the third insulating layer 13. In addition, when the thickness T5 of the piezoelectric layer 15 is about 0.1λ, and as the thickness T3 of the third insulating layer 13 increases, the anisotropic coefficient γ increases. For example, from the viewpoint of setting the anisotropic coefficient γ to be equal to or more than 1.7, when the electrode finger 21 includes the tungsten layer, the thickness of the tungsten layer is preferably equal to or more than 250 nm. When this is generalized to a case where a layer other than the tungsten layer is included, it is preferable that a layer satisfying T≥(19.25×250)/ρ is included in a case where the thickness of the layer included in the electrode finger 21 is T and the density thereof is ρ.

According to the first embodiment, the anisotropy coefficient γ in the intersection region 30 where the electrode fingers 21 of the pair of interdigitated electrodes 20 provided on the piezoelectric layer 15 intersect with each other is 1.7 or more. As a result, as illustrated in FIG. 3B to FIG. 3E, the interval of the transverse mode spurious emissions on the higher frequency side than the resonant frequency is widened, and thus the number of transverse mode spurious emissions in a predetermined frequency range from the resonant frequency can be reduced. That is, the number of transverse mode spurious emissions can be reduced in the wide frequency range on the higher frequency side than the resonant frequency. Therefore, the influence of the transverse mode spurious can be reduced over the wide band.

From the viewpoint of reducing the influence of the transverse mode spurious emissions, the anisotropy coefficient γ in the intersection region 30 is preferably equal to or more than 3.0, more preferably equal to or more than 5.0, and still more preferably equal to or more than 7.0. Since the electrode finger 21 becomes thicker as the anisotropy coefficient γ increases and adverse effects on characteristics other than transverse mode spurious emissions are considered, the anisotropy coefficient γ in the intersection region 30 is preferably 20 or less, more preferably 15 or less, and still more preferably 10 or less from the viewpoint of miniaturization and suppression of deterioration of other characteristics.

In the first embodiment, the thickness T5 of the piezoelectric layer 15 is equal to or less than 1.0λ. In other words, the thickness T5 of the piezoelectric layer 15 is equal to or less than about 2.0 times the average pitch D of the plurality of electrode fingers 21. In such a case, as illustrated in FIG. 3A, when the anisotropy coefficient γ is small, many transverse mode spurious emissions are likely to occur on the higher frequency side than the resonance frequency. However, by setting the anisotropy coefficient γ to 1.7 or more, the interval of the transverse mode spurious emissions can be widened, and the number of transverse mode spurious emissions in a predetermined frequency range from the resonance frequency can be reduced. That is, the number of transverse mode spurious emissions can be reduced in the wide frequency range on the higher frequency side than the resonant frequency. Therefore, the influence of the transverse mode spurious can be reduced over the wide band.

The thickness T5 of the piezoelectric layer 15 is preferably 0.05λ or more and 0.3λ or less. In other words, the thickness T5 of the piezoelectric layer 15 is preferably 0.1 times or more and 0.6 times or less the average pitch D of the plurality of electrode fingers 21, for example. This makes it possible to increase the anisotropy coefficient γ as illustrated in FIG. 5B. From the viewpoint of increasing the anisotropic coefficient γ, the thickness T5 of the piezoelectric layer 15 is preferably equal to or more than 0.12 times and equal to or less than 0.55 times, more preferably equal to or more than 0.15 times and equal to or less than 0.5 times, and still more preferably equal to or more than 0.18 times and equal to or less than 0.4 times the average pitch D.

In the first embodiment, the third insulating layer 13 which is a silicon oxide layer is provided between the substrate 10 and the piezoelectric layer 15. The thickness T3 of the third insulating layer 13 is preferably more than 0.2λ, that is, more than 0.4 times the average pitch D of the plurality of electrode fingers 21. This makes it possible to increase the anisotropy coefficient γ as illustrated in FIG. 5C. From the viewpoint of increasing the anisotropic coefficient γ, the thickness T3 of the third insulating layer 13 is preferably equal to or more than 0.25λ, more preferably equal to or more than 0.30λ, and still more preferably equal to or more than 0.35λ. From the viewpoint of causing the energy of the acoustic wave of the main response to exist in the third insulating layer 13 and causing the third insulating layer 13 to function as a temperature compensation film, the thickness T3 of the third insulating layer 13 is preferably equal to or less than 1.0λ, more preferably equal to or less than 0.8λ, and still more preferably equal to or less than 0.6λ.

### Second Embodiment

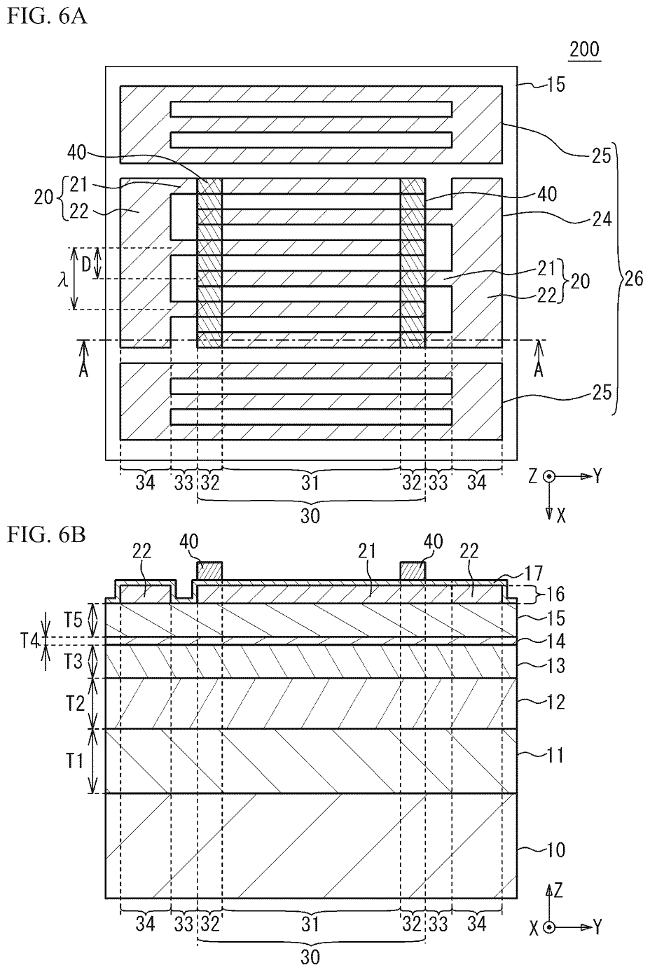

A second embodiment will also describe an example in which an acoustic wave device includes an acoustic wave resonator. FIG. 6A is a plan view of an acoustic wave device 200 according to the second embodiment, and FIG. 6B is a cross-sectional view taken along a line A-A in FIG. 6A. As illustrated in FIGS. 6A and 6B, the intersection region 30, which is a region where the electrode fingers 21 of the pair of interdigitated electrodes 20 intersect with each other, includes edge regions 32 which is regions located at edges in the Y direction, and a central region 31 which is a region located inside the edge regions 32 in the Y direction. The edge region 32 can also be said to be a region in which the tips of the electrode fingers 21 are located. Regions located between the tips of the electrode fingers 21 of one of the interdigitated electrodes 20 and the busbar 22 of the other of the interdigitated electrodes 20 are gap regions 33. Regions where the busbars 22 are located are busbar regions 34. Load films 40 are provided on the piezoelectric layer 15 in the edge regions 32. The load film 40 is provided in a band shape in the X direction and covers the electrode fingers 21 located in the edge region 32. The load film 40 is not provided in the central region 31, the gap region 33, and the busbar region 34. The load film 40 is an insulating film containing, for example, silicon oxide (SiO₂), tantalum oxide (Ta₂O₅), or niobium oxide (Nb₂O₅) as a main component. The load film 40 may be a single-layer or multilayer film including another material as a main component as long as the acoustic velocity of the acoustic wave propagating through the edge region 32 is adjustable. The other configurations of the second embodiment are the same as those of the first embodiment, and thus the description thereof will be omitted.

### [Manufacturing Method]

A method of manufacturing the acoustic wave device 200 according to the second embodiment will be described. First, the first insulating layer 11, the second insulating layer 12, the third insulating layer 13, the fourth insulating layer 14, and the piezoelectric layer 15 are formed on the substrate 10, and then the IDT 24 and the reflectors 25 are formed on the piezoelectric layer 15. These are formed by the same method as that described in the first embodiment. Next, the load film 40 covering the electrode fingers 21 is formed on the piezoelectric layer 15 in the edge region 32. The load film 40 is formed by, for example, forming a mask layer having an aperture in the edge region 32 on the piezoelectric layer 15, forming the load film 40 using the mask layer as a mask, and then removing the mask layer. The mask layer is formed of, for example, a photoresist. The load film 40 is formed by, for example, the sputtering method, the CVD method, or the vacuum deposition method. Thus, the acoustic wave device 200 according to the second embodiment is formed.

### [Acoustic Velocity of Acoustic Wave]

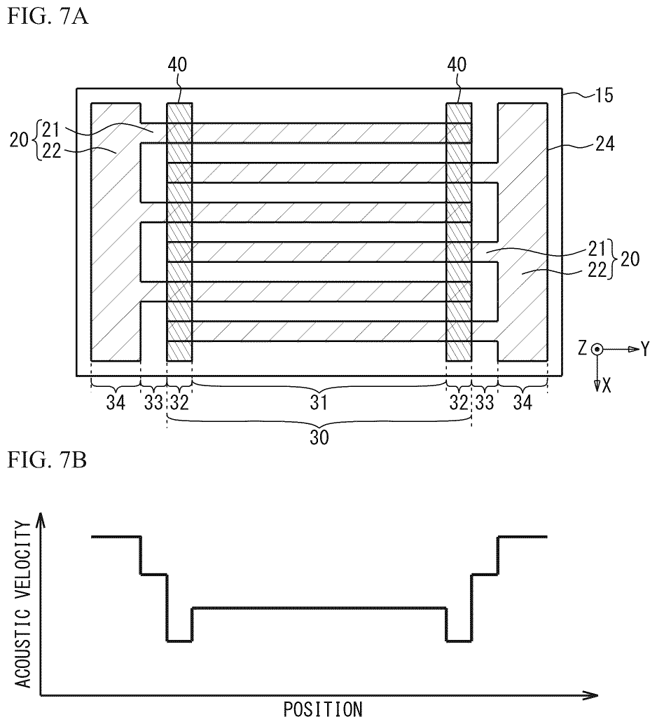

FIG. 7A is a plan view of the IDT 24 in the second embodiment, and FIG. 7B is a diagram illustrating the acoustic velocity of an acoustic wave in the second embodiment. As illustrated in FIGS. 7A and 7B, since the load film 40 is provided in the edge region 32, the acoustic velocity of the acoustic wave propagating through the edge region 32 is lower than the acoustic velocity of the acoustic wave propagating through the central region 31. Since the number of electrode fingers 21 in the gap region 33 is smaller than that in the central region 31, the acoustic velocity of the acoustic wave propagating through the gap region 33 is higher than the acoustic velocity of the acoustic wave propagating through the central region 31. The acoustic velocity of the acoustic wave propagating through the busbar region 34 is higher than the acoustic velocity of the acoustic wave propagating through the gap region 33, for example. Accordingly, the edge region 32 is a low acoustic velocity region in which the acoustic velocity of the acoustic wave is lower than that in the central region 31, and the gap region 33 is a high acoustic velocity region in which the acoustic velocity of the acoustic wave is higher than that in the central region 31, and thus, a piston mode can be achieved. The acoustic velocity of the acoustic wave is expressed by the above-described Equation 1.

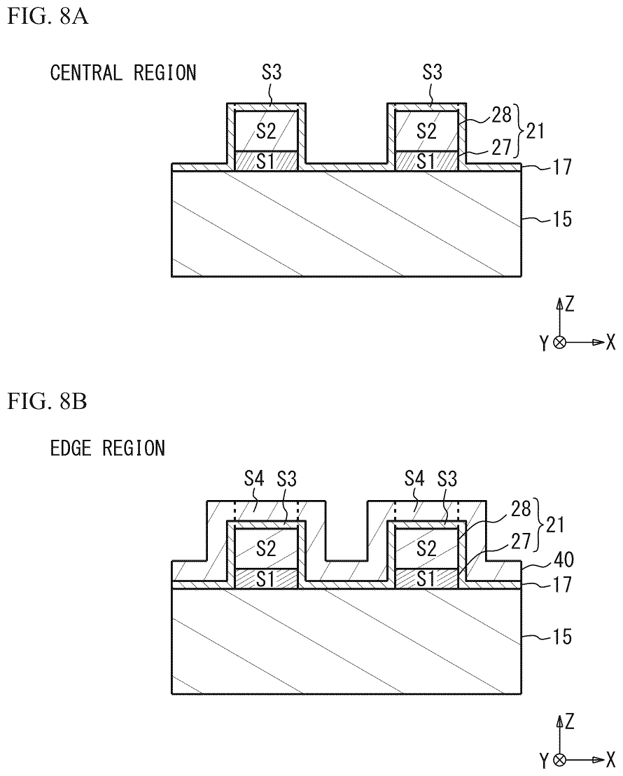

FIGS. 8A and 8B are cross-sectional views of the electrode fingers 21 in the second embodiment. FIG. 8A is a cross-sectional view of the electrode fingers 21 in the central region 31 in the X direction. FIG. 8B is a cross-sectional view of the electrode fingers 21 in the edge region 32 in the X direction. In FIGS. 8A and 8B, the electrode finger 21 is illustrated as a multilayer film in which a first metal film 27 and a second metal film 28 are stacked, but may be a single-layer film. As illustrated in FIGS. 8A and 8B, the width and the height of the electrode finger 21 in the central region 31 are substantially the same as those in the edge region 32, and the thickness of the insulating film 17 in the central region 31 is also substantially the same as that in the edge region 32.

As illustrated in FIG. 8A, the cross-sectional area of the first metal film 27 is denoted by S1, the cross-sectional area of the second metal film 28 is denoted by S2, and the cross-sectional area of the insulating film 17 on the electrode finger 21 is denoted by S3. Further, the density of the metal material of the main component of the first metal film 27 is denoted by ρ1, the density of the metal material of the main component of the second metal film 28 is denoted by ρ2, and the density of the constituent material of the main component of the insulating film 17 is denoted by ρ3. In this case, the weight per unit length in the Y direction obtained by multiplying the cross-sectional area of the first metal film 27 by the concentration is S1×ρ1. The weight per unit length in the Y direction obtained by multiplying the cross-sectional area of the second metal film 28 by the concentration is S2×ρ2. The weight per unit length in the Y direction obtained by multiplying the cross-sectional area of the insulating film 17 by the thickness is S3×ρ3. Therefore, in the central region 31, the weight per unit length in the Y direction of the film including the metal film of the electrode fingers 21 provided on the piezoelectric layer 15 at the positions where the electrode fingers 21 are located (referred to as a first weight) is (S1×ρ1)+ (S2×ρ2)+ (S3×ρ3).

As illustrated in FIG. 8B, in the edge region 32, the load film 40 is provided on the electrode finger 21 in addition to the insulating film 17. The cross-sectional area of the load film 40 on the electrode finger 21 is denoted by S4. The density of the constituent material of the main component of the load film 40 is denoted by ρ4. In this case, the weight per unit length in the Y direction obtained by multiplying the cross-sectional area of the load film 40 by the concentration is S4×ρ4. Thus, the weight per unit length in the Y direction of the film including the metal film of the electrode fingers 21 provided on the piezoelectric layer 15 at the positions where the electrode fingers 21 are located (referred to as a second weight) is (S1×ρ1)+ (S2×ρ2)+ (S3×ρ3)+ (S4×ρ4). Thus, the second weight is more than the first weight.

Since the second weight is more than the first weight, the acoustic velocity of the acoustic wave propagating through the edge region 32 is lower than the acoustic velocity of the acoustic wave propagating through the central region 31 as illustrated in FIG. 7. Thus, the piston mode can be realized. As described above, in the central region 31 and the edge region 32, the weight per unit length in the Y direction of the film provided on the piezoelectric layer 15 at the positions where the electrode fingers 21 are located can be calculated from the cross-sectional area and the density of the constituent material by observing the cross-section of the electrode fingers 21 in the central region 31 and the edge region 32.

### [Simulation 3: Simulation on Transverse Mode Spurious Emissions]

A simulation was performed using two dimensional analysis software to examine the transverse mode spurious emissions when the anisotropy coefficient γ in the intersection region 30 was varied in the second embodiment. The simulation conditions are as follows.
Wavelength λ of acoustic wave: 4.17 μm
Number of pairs of electrode fingers 21: 100 pairs
Aperture length: 15%
Duty ratio: 50%
Length of gap region 33 in Y direction: 1λ
Difference in acoustic velocity between central region 31 and edge region 32: 0.5%
Difference in acoustic velocity between central region 31 and gap region 33: 24%
Anisotropy coefficient γ of intersection region 30: 0.3, 1.7, 10, 17

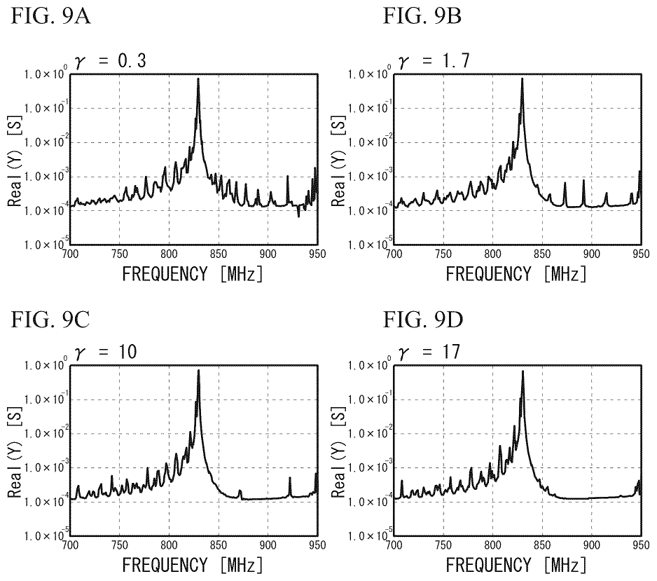

FIGS. 9A to 9D are diagrams illustrating simulation results of real part Real (Y) of admittance with respect to frequency. FIG. 9A illustrates the results when the anisotropy coefficient γ is 0.3, FIG. 9B illustrates the results when γ is 1.7, FIG. 9C illustrates the results when γ is 10, and FIG. 9D illustrates the results when γ is 17. As illustrated in FIG. 9A to 9D, even when the load film 40 is provided in the edge region 32 and the piston mode is established, when the anisotropy coefficient γ increases, the interval of the transverse mode spurious emissions increases on the higher frequency side than the resonance frequency, and the number of transverse mode spurious emissions decreases in a predetermined frequency range from the resonance frequency. That is, the number of transverse mode spurious emissions decreases in the wide frequency range on the high frequency side of the resonant frequency, and the admittance is suppressed by the piston mode over a range from the resonant frequency to the vicinity of 950 MHz, which is the stop band of the reflection of the bulk wave. Since the frequency at which the transverse mode spurious emissions increase is limited when the anisotropy coefficient increases, the transverse mode spurious emissions can be reduced by the piston mode.

From the results of the simulation 3, it is understood that, even when the piston mode is established, the interval of the transverse mode spurious emission becomes wide on the higher frequency side than the resonance frequency by setting the anisotropy coefficient γ to 1.7 or more, and the influence of the transverse mode spurious emission can be reduced in the wide frequency range on the higher frequency side than the resonance frequency. It is also found that, when the piston mode is established, the strength of the transverse mode spurious emissions can be reduced by setting the anisotropy coefficient γ to 1.7 or more.

### Modifications

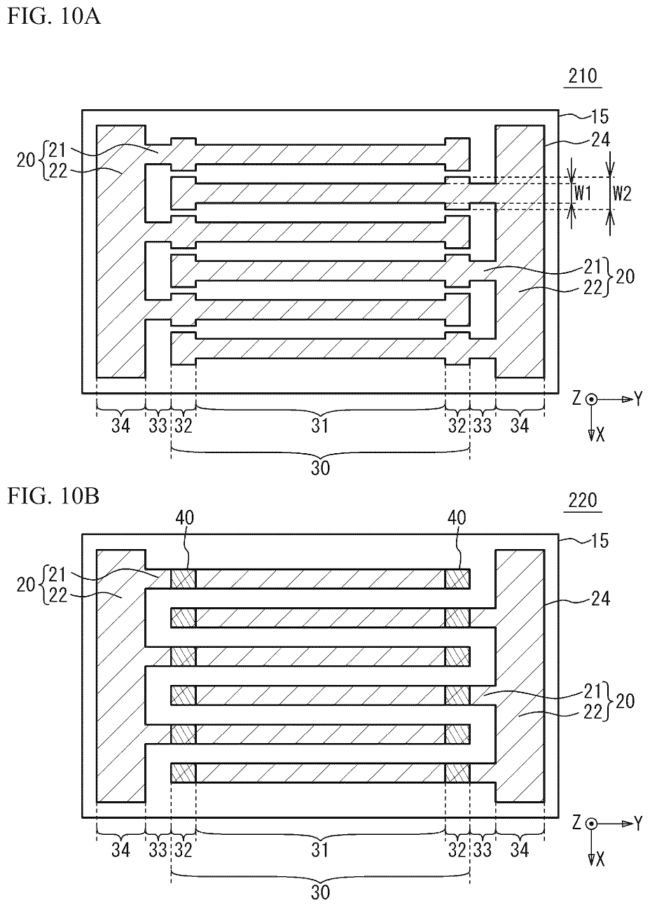

FIG. 10A is a plan view of an acoustic wave device 210 according to a first modification of the second embodiment. As illustrated in FIG. 10A, in the first modification of the second embodiment, no load film is provided in the edge region 32. Instead, the width W2 of each of the electrode fingers 21 in the edge regions 32 is larger than the width W1 of each of the electrode fingers 21 in the central region 31. The other configurations of the first modification of the second embodiment are the same as those of the second embodiment, and thus the description thereof will be omitted.

FIG. 10B is a plan view of an acoustic wave device 220 according to a second modification of the second embodiment. As illustrated in FIG. 10B, in the second modification of the second embodiment, the load film 40 provided in the edge region 32 is provided only on the electrode fingers 21 and is not provided between the electrode fingers 21. That is, the load film 40 is provided in a band shape in the second embodiment, whereas the load film 40 is provided in a dot shape in the second modification of the second embodiment. The other configurations of the second modification of the second embodiment are the same as those of the second embodiment, and thus the description thereof will be omitted.

Also in the first and second modifications of the second embodiment, regarding the weight per unit length in the Y direction of the single-layer or multilayer film including the metal layer of the electrode fingers 21 provided on the piezoelectric layer 15 at the positions where the electrode fingers 21 are located, the second weight in the edge region 32 is more than the first weight in the central region 31. Therefore, as in FIG. 7, the acoustic velocity of the acoustic wave propagating through the edge region 32 is lower than the acoustic velocity of the acoustic wave propagating through the central region 31.

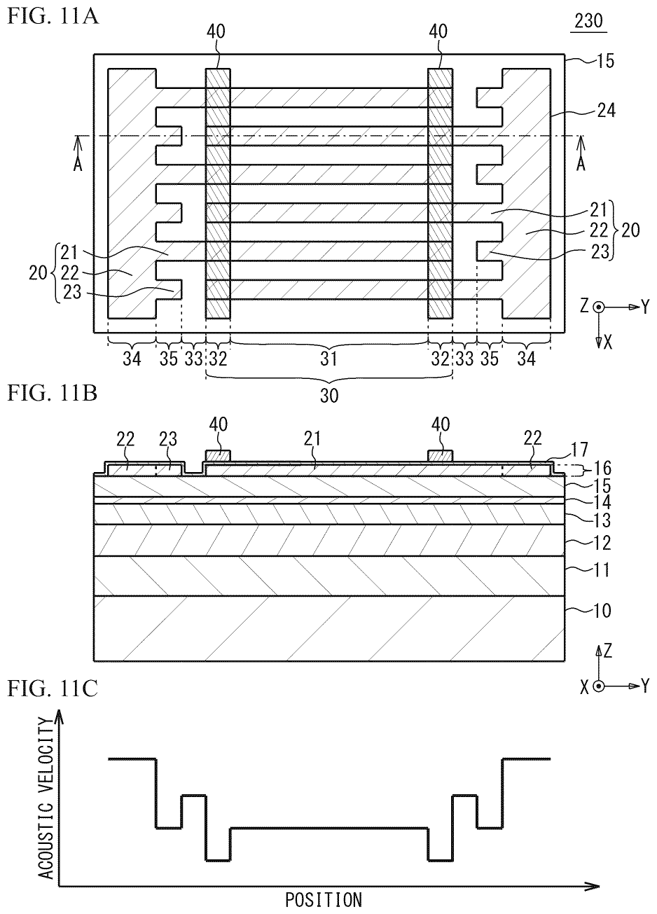

FIG. 11A is a plan view of an acoustic wave device 230 according to a third modification of the second embodiment, and FIG. 11B is a cross-sectional view taken along a line A-A in FIG. 11A. As illustrated in FIGS. 11A and 11B, in the third modification of the second embodiment, the interdigitated electrode 20 includes a plurality of dummy electrode fingers 23 connected to the busbar 22 in addition to the plurality of electrode fingers 21 and the busbar 22. The tips of the electrode fingers 21 of one of the pair of interdigitated electrodes 20 face the tips of the dummy electrode fingers 23 of the other of the pair of interdigitated electrodes 20. Regions located between the electrode fingers 21 and the dummy electrode fingers 23 are the gap regions 33. Regions where the dummy electrode fingers 23 are located are dummy regions 35. The other configurations of the third modification of the second embodiment are the same as those of the second embodiment, and thus the description thereof will be omitted.

FIG. 11C is a diagram illustrating an acoustic velocity of the acoustic wave in the third modification of the second embodiment. As illustrated in FIG. 11C, since the dummy electrode fingers 23 are provided in the dummy region 35, the acoustic velocity of the acoustic wave propagating through the dummy region 35 is the same as the acoustic velocity of the acoustic wave propagating through the central region 31. The other configurations of the acoustic velocity are the same as those of the acoustic velocity in FIG. 7, and thus the description thereof will be omitted.

As described above, the interdigitated electrode 20 may include the plurality of electrode fingers 21, the plurality of dummy electrode fingers 23, and the busbar 22 to which the electrode fingers 21 and the dummy electrode fingers 23 are connected. In the first embodiment, the interdigitated electrode 20 may include the dummy electrode fingers 23.

In the second embodiment and the modifications thereof, the anisotropy coefficient γ in the intersection region 30 where the electrode fingers 21 of the pair of interdigitated electrodes 20 provided on the piezoelectric layer 15 intersect with each other is 1.7 or more. As a result, as illustrated in FIGS. 9B to 9D, the interval of the transverse mode spurious emissions on the higher frequency side than the resonant frequency increases, and thus the number of transverse mode spurious emissions in a predetermined frequency range from the resonant frequency can be reduced. That is, the number of transverse mode spurious emissions can be reduced in the wide frequency range on the higher frequency side than the resonant frequency. Therefore, the influence of the transverse mode spurious emissions can be reduced over the wide band.

In the second embodiment and the modifications thereof, as illustrated in FIGS. 8A and 8B, the weight per unit length in the Y direction of the single-layer or multilayer film including the metal film of the electrode fingers 21 provided on the piezoelectric layer 15 at the positions where the electrode fingers 21 are located is larger in the edge region 32 than in the central region 31. That is, as illustrated in FIG. 7, the acoustic velocity of the acoustic wave propagating through the edge region 32 is lower than the acoustic velocity of the acoustic wave propagating through the central region 31. This makes it possible to realize the piston mode. In this case, when the anisotropy coefficient γ in the intersection region 30 is 1.7 or more, as illustrated in FIGS. 9B to 9D, the number of transverse mode spurious emissions can be reduced in the wide frequency range on the higher frequency side than the resonant frequency, and the strength of the transverse mode spurious emissions can be reduced. Therefore, the influence of the transverse mode spurious can be further reduced over the wide band.

From the viewpoint of realizing the piston mode, the second weight is preferably more than 1.0 times and less than 2.0 times, more preferably 1.05 times or more and 1.6 times or less, and further preferably 1.1 times or more and 1.4 times or less the first weight. The electrode fingers 21 having the second weight larger than the first weight are preferably 70% or more, more preferably 80% or more, still more preferably 90% or more, and most preferably all of the plurality of electrode fingers 21.

In the second embodiment and the modifications thereof, the anisotropy coefficient γ in the intersection region 30 is preferably 3.0 or more, more preferably 5.0 or more, and still more preferably 7.0 or more, as in the first embodiment. The anisotropy coefficient γ in the intersection region 30 is preferably 20 or less, more preferably 15 or less, and still more preferably 10 or less. The thickness T5 of the piezoelectric layer 15 is preferably equal to or less than 2.0 times the average pitch D of the plurality of electrode fingers 21, and more preferably equal to or more than 0.1 times and equal to or less than 0.6 times the average pitch D. The thickness T3 of the third insulating layer 13, which is a silicon oxide layer, is preferably more than 0.4 times the average pitch D of the plurality of electrode fingers 21.

In the second embodiment and the modifications thereof, the acoustic velocity of the acoustic wave propagating through the edge region 32 is made lower than the acoustic velocity of the acoustic wave propagating through the central region 31 by providing the load film 40 in the edge region 32 or by increasing the widths W2 of the electrode fingers 21 in the edge region 32, but other methods may be used.

### Third Embodiment

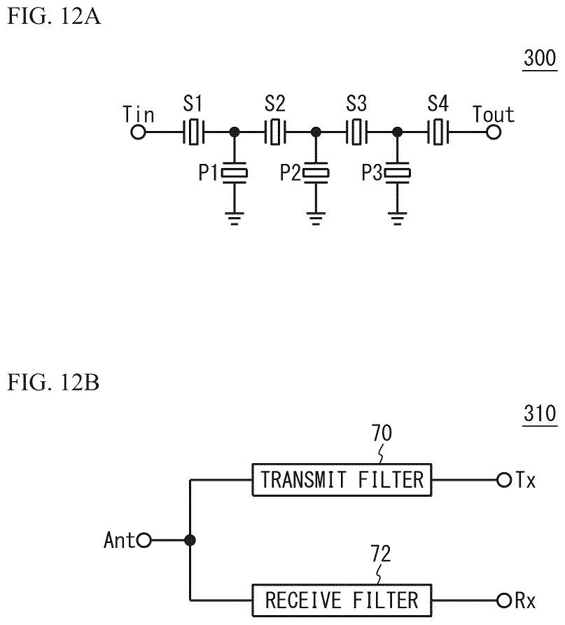

FIG. 12A is a circuit diagram of a filter 300 according to a third embodiment. As illustrated in FIG. 12A, one or more series resonators S1 to S4 are connected in series between an input terminal Tin and an output terminal Tout. One or more parallel resonators P1 to P3 are connected in parallel between the input terminal Tin and an output terminal Tout. The acoustic wave devices of the first embodiment, the second embodiment, and the variations thereof can be used for at least one of the series resonators S1 to S4 and the parallel resonators P1 to P3. The number of series resonators and parallel resonators, and the like can be set as appropriate. Although the ladder-type filter is illustrated as an example of the filter, the filter may be a multi-mode filter.

FIG. 12B is a circuit diagram of a duplexer 310 according to a modification of the third embodiment. As illustrated in FIG. 12B, a transmit filter 70 is connected between a common terminal Ant and a transmit terminal Tx. A receive filter 72 is connected between the common terminal Ant and a receive terminal Rx. The transmit filter 70 transmits signals in the transmit band to the common terminal Ant as transmission signals among high frequency signals input from the transmit terminal Tx, and suppresses signals with other frequencies. The receive filter 72 transmits signals in the receive band to the receive terminal Rx as receive signals among high frequency signals input from the common terminal Ant, and suppresses signals with other frequencies. At least one of the transmit filter 70 and the receive filter 72 may be the filter of the third embodiment. Although a duplexer is illustrated as an example of a multiplexer, a triplexer or a quadplexer may be used.

Although the embodiments of the present disclosure have been described in detail above, the present disclosure is not limited to the specific embodiments, and various change, substitutions, and alterations could be made hereto without departing from the spirit and scope of the claimed invention.

What is claimed is:

1. An acoustic wave device comprising:
a substrate;
a piezoelectric layer provided on the substrate; and
a pair of interdigitated electrodes provided on the piezoelectric layer, each of the interdigitated electrodes including a plurality of electrode fingers that excite an acoustic wave and a busbar to which the plurality of electrode fingers are connected;
wherein an anisotropic coefficient γ represented by kₓ²+γk_{y}²=k₀² is equal to or more than 1.7, where kₓ is a wavenumber of the acoustic wave in an arrangement direction of the plurality of fingers, k_{y} is a wavenumber of the acoustic wave in a longitudinal direction of the plurality of fingers, and k₀ is a wavenumber of the acoustic wave in a direction inclined from the arrangement direction toward the longitudinal direction.

2. The acoustic wave device according to claim 1,
wherein the pair of interdigitated electrodes include an intersection region in which the plurality of electrode fingers of one of the pair of interdigitated electrodes intersect with the plurality of electrode fingers of another of the pair of interdigitated electrodes, and a gap region located between the intersection region and the busbar and adjacent to the intersection region,
wherein the intersection region includes edge regions located at edges in the longitudinal direction and a central region located inside the edge regions, and
wherein a weight per unit length in the longitudinal direction of a single-layer or multilayer film including a metal film of the plurality of electrode fingers provided on the piezoelectric layer at positions where the plurality of electrode fingers are located is larger in the edge regions than in the central region.

3. The acoustic wave device according to claim 1,
wherein the pair of interdigitated electrodes include an intersection region in which the plurality of electrode fingers of one of the pair of interdigitated electrodes intersect with the plurality of electrode fingers of another of the pair of interdigitated electrodes, and a gap region located between the intersection region and the busbar and adjacent to the intersection region,
wherein the intersection region includes edge regions located at edges in the longitudinal direction and a central region located inside the edge regions, and
wherein an acoustic velocity of the acoustic wave propagating through the edge regions is lower than an acoustic velocity of the acoustic wave propagating through the central region.

4. The acoustic wave device according to claim 1,
wherein a thickness of the piezoelectric layer is equal to or less than 2.0 times an average pitch of the plurality of electrode fingers.

5. The acoustic wave device according to claim 1,
wherein the anisotropy coefficient γ is 20 or less.

6. The acoustic wave device according to claim 1,
wherein the anisotropy coefficient γ is 3.0 or more.

7. The acoustic wave device according to claim 1,
wherein a thickness of the piezoelectric layer is equal to or more than 0.1 times and equal to or less than 0.6 times an average pitch of the plurality of electrode fingers.

8. The acoustic wave device according to claim 1, further comprising a silicon oxide layer provided between the substrate and the piezoelectric layer, the silicon oxide layer having a thickness more than about 0.4 times an average pitch of the plurality of electrode fingers.

9. The acoustic wave device according to claim 1,
wherein each of the plurality of electrode fingers includes a metal film containing tungsten as a main component.

10. The acoustic wave device according to claim 1,
wherein each of the plurality of electrode fingers includes a multilayer film containing a titanium adhesion layer and a tungsten layer.

11. The acoustic wave device according to claim 1,
wherein each of the plurality of electrode fingers includes a tungsten film having a thickness of 250 nm or more.

12. The acoustic wave device according to claim 2,
wherein the anisotropy coefficient in the intersection region is 3.0 or more.

13. The acoustic wave device according to claim 1, further comprising a silicon oxide layer provided between the substrate and the piezoelectric layer, the silicon oxide layer having a thickness of 0.2 to 1.0 times a wavelength of the acoustic wave.

14. The acoustic wave device according to claim 1, further comprising a silicon oxide layer provided between the substrate and the piezoelectric layer, as a temperature compensation film.

15. The acoustic wave device according to claim 1,
wherein the piezoelectric layer is a rotated Y-cut X-propagation LiTaO₃ layer or a rotated Y-cut X-propagation LiNbO₃ layer.

16. The acoustic wave device according to claim 2,
wherein a width of each of the plurality of electrode fingers in the edge regions is larger than a width of each of the plurality of electrode fingers in the central region.

17. The acoustic wave device according to claim 1, further comprising
a load film patterned in a dot shape on the piezoelectric layer.

18. A filter comprising the acoustic wave device according to claim 1.

19. A multiplexer comprising a filter according to claim 18.
